(19) United States
(12) Patent Application Publication
(10) Pub. No.: US 2013/0256894 A1
(43) Pub. Date: Oct. 3, 2013

(54) Porous Metallic Film as Die Attach and Interconnect

(71) Applicant: INTERNATIONAL RECTIFIER CORPORATION, El Segundo, CA (US)

(72) Inventor: Gretchen Adema, Raleigh, NC (US)

(73) Assignee: INTERNATIONAL RECTIFIER CORPORATION, EL SEGUNDO, CA (US)

(21) Appl. No.: 13/655,983

(22) Filed: Oct. 19, 2012

Related U.S. Application Data
(60) Provisional application No. 61/617,584, filed on Mar. 29, 2012.

(51) Int. Cl. H01L 23/482; H01L 21/50

(52) U.S. Cl. 257/762; 438/121; 257/E23.017; 257/E21.499

(57) ABSTRACT

One exemplary disclosed embodiment comprises a sintered porous metallic film as a die attach mechanically connecting a backside of a semiconductor die to a substrate of a package. Another exemplary disclosed embodiment comprises a sintered porous metallic film as an electrical connection between an electrode on an active surface of a semiconductor die and a substrate of a package. The porous metallic film may be integrated as a prefabricated film or may be created at the wafer or substrate level. By providing a conformal bond through the presence of pores in the metallic film, the sintered connection can provide a reliable mechanical connection with a lower effective elastic modulus. Thermal expansion stresses between die and substrate are thereby accommodated for robustness against thermal cycling, which is of particular relevance for high performance power modules and automotive applications.

The present application claims the benefit of and priority to a pending provisional application entitled “Porous Metallic Film as Die Attach and Interconnect,” Ser. No. 61/617,584 filed on Mar. 29, 2012. The disclosure in this pending provisional application is hereby incorporated fully by reference into the present application.

### BACKGROUND OF THE INVENTION

1. Field of the Invention

The present invention relates generally to semiconductor devices. More particularly, the present invention relates to packaging of semiconductor devices.

2. Background Art

High lead solder has a long history of use in the semiconductor industry as a die attach and interconnect material within semiconductor packages. By providing low resistance and high thermal conductivity for improved electrical performance, ductility to accommodate thermal expansion mismatches between joining materials, and a high melting temperature to sustain multiple reflow cycles, high lead solder is an ideal material for die attach and interconnect purposes. Thus, high lead solder can provide reliable, high performance bonds between materials, such as between a die and a substrate of a semiconductor package.

However, for environmental toxicity reasons and to comply with regulations such as the Restriction of Hazardous Substances Directive (RoHS), lead-free alternatives to high lead solder are desirable. While various lead-free solder alloys are available, many are unsuitable as direct substitutions for high lead solder, particularly for power modules. For example, to meet Q101 automotive level qualification requirements, a surface mount package must attain a moisture sensitivity level 1 rating (MSL-1). Accordingly, a surface mount package for automotive applications must be able to withstand three reflows at 260° C. using a lead-free board level assembly process. Thus, many lead-free solder alloys with low melting temperatures are eliminated from consideration.

While some lead-free solder alloys with sufficiently high melting temperatures above 260° C. exist, various drawbacks preclude their use as a reliable, cost effective, and high performance die attach and interconnect material. For example, 80Au20Su provides high electrical and thermal conductivity but also suffers from high material costs and hardness, resulting in increased fabrication costs and susceptibility to thermal mismatch stress. Bi11AgGe provides a strong mechanical bond but suffers from low conductivity and does not form intermetallics with nickel, a standard joining material. Zn6Al provides high conductivity but suffers from corrosion issues, low workability, and higher than desirable melting temperature.

Thus, a unique cost-effective solution with high performance and reliability is needed to replace high lead solder as a die attach and interconnect within semiconductor packages.

### SUMMARY OF THE INVENTION

A porous metallic film as a die attach and an interconnect in a semiconductor package, substantially as shown in and/or described in connection with at least one of the figures, and as set forth more completely in the claims.

### BRIEF DESCRIPTION OF THE DRAWINGS

FIG. 1A illustrates a cross sectional view of a semiconductor package utilizing a porous metallic film as a die attach, according to an embodiment of the invention.

FIG. 1B illustrates a cross sectional view of a semiconductor package utilizing a porous metallic film as an interconnect, according to an embodiment of the invention.

FIG. 2A illustrates a cross sectional view of a semiconductor package utilizing a non-porous metallic film as a die attach.

FIG. 2B illustrates a cross sectional view of a semiconductor package utilizing a porous metallic film as a die attach, according to an embodiment of the invention.

FIG. 3A illustrates a table comparing properties of conventional materials for die attach and interconnect within a package.

FIG. 3B illustrates a table showing properties of sintered porous metallic films for die attach and interconnect within a package, according to an embodiment of the invention.

### DETAILED DESCRIPTION OF THE INVENTION

The present application is directed to a porous metallic film as a die attach and an interconnect in a semiconductor package. The following description contains specific information pertaining to the implementation of the present invention. One skilled in the art will recognize that the present invention may be implemented in a manner different from that specifically discussed in the present application. Moreover, some of the specific details of the invention are not discussed in order not to obscure the invention. The specific details not described in the present application are within the knowledge of a person of ordinary skill in the art.

The drawings in the present application and their accompanying detailed description are directed to merely exemplary embodiments of the invention. To maintain brevity, other embodiments of the invention, which use the principles of the present invention, are not specifically described in the present application and are not specifically illustrated by the present drawings.

To replace lead-free solder as a die attach in a package, it has been proposed to apply specially formulated silver pastes to form a sintered connection between a die and a substrate. For example, one approach is to apply high mechanical pressure, such as 30 MPa, to form a sintered bond using a proprietary silver paste. However, the risk of damage to the die and substrate and the requirement for specialized high pressure workholders and equipment makes the process unwieldy for practical use. To avoid the above problems, alternative solutions using silver pastes with nano-sized particles have been formulated, which require low or zero mechanical pressure. Unfortunately, the required use of solvents to maintain the consistency of the nano silver paste formulation necessitates the removal of the solvents after sintering, a difficult process that may leave large voids remaining as an undesirable side effect. Moreover, this requirement means that the nano paste sintering process must be tailored to each individual application and may have a maximum die size limitation, limiting its feasibility as a commercially applicable technique.

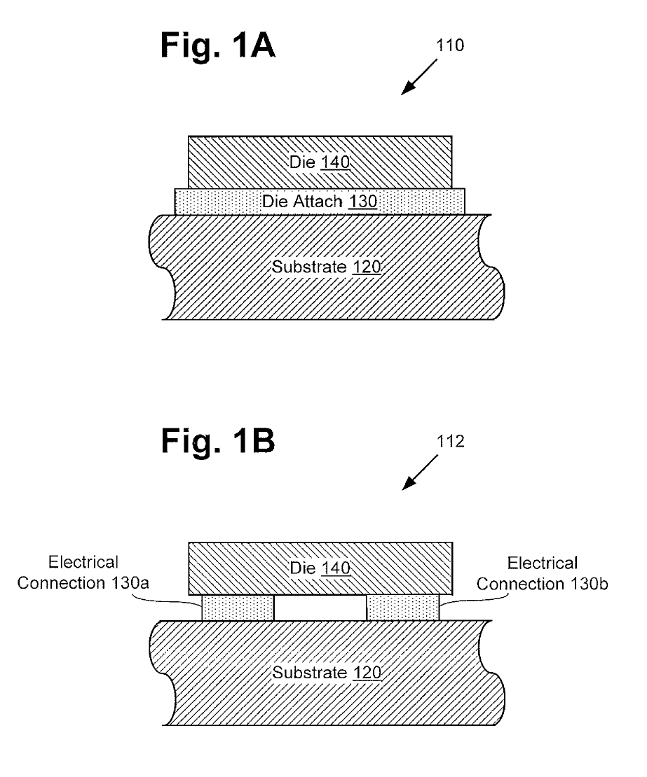

Accordingly, FIG. 1A illustrates a cross sectional view of a semiconductor package utilizing a porous metallic film as a die attach, according to an embodiment of the invention. Package 110 of FIG. 1A includes substrate 120, die attach 130, and die 140. Substrate 120 may comprise any substrate, for example a direct bonded copper (DBC) substrate or a ceramic substrate. Die attach 130 comprises a porous metallic film, for example a porous silver film, although other metals or metallic compounds may be utilized such as copper. Die 140 may comprise any semiconductor device, for example a power module such as a MOSFET, a HEMT, or an IGBT. In package 110 of FIG. 1A, the backside of die 140 may be mechanically and thermally but not electrically connected to substrate 120 via die attach 130. In alternative embodiments, die 140 may comprise a vertical conduction device, wherein die 140 is mechanically and electrically connected to substrate 120 via die attach 130. For simplicity, connections are omitted from a top side of die 140, which may include conductive clips, wire bonds, ribbon bonds, stacked dies, or other additional elements of package 110. Moreover, only a portion of substrate 120 may be illustrated, and encapsulating structures such as mold compounds or hermetic seals may be omitted.

Since die attach 130 comprises a porous metallic film rather than a nano-particle paste, the use of solvents in the sintering process can be minimized or avoided, thus avoiding the above discussed issue of large voids in the sintered bond. Moreover, the sintering process may be generally applicable to any sized die and any package application. It has been demonstrated that a combination of low mechanical bond pressure below 10 MPa, such as 6.9 MPa, and moderate temperature corresponding to standard reflow temperatures between 200 to 300 degrees C., such as 250 degrees C., is sufficient to create the solid state sintered bond of die attach 130. Thus, the use of specialized high pressure workholders and equipment may be avoided, reducing the risk of damage to package 110.

Besides functioning as a die attach, porous metallic films may also replace other bonds where solder is conventionally utilized. Thus, FIG. 1B illustrates a cross sectional view of a semiconductor package utilizing a porous metallic film as an interconnect, according to an embodiment of the invention. Package 112 of FIG. 1B includes substrate 120, electrical connection 130a and 130b, and die 140. With respect to FIG. 1B, like numbered elements may correspond to similar elements from FIG. 1A.

Assuming die 140 may comprise a planar MOSFET flipped such that an active surface is facing substrate 120, electrical connection 130a may mechanically and electrically connect a source electrode of die 140 to substrate 120, and electrical connection 130b may mechanically and electrically connect a drain electrode of die 140 to substrate 120. Electrical connection 130a and electrical connection 130b may comprise sections of a porous metallic film, and may comprise the same material as die attach 130 from package 110 of FIG. 1A. Thus, the porous metallic film may also serve as an interconnect between die 140 and substrate 120. Although two electrical connections are shown in FIG. 1B, the number of electrical connections is only exemplary and alternative embodiments may use any number of electrical connections.

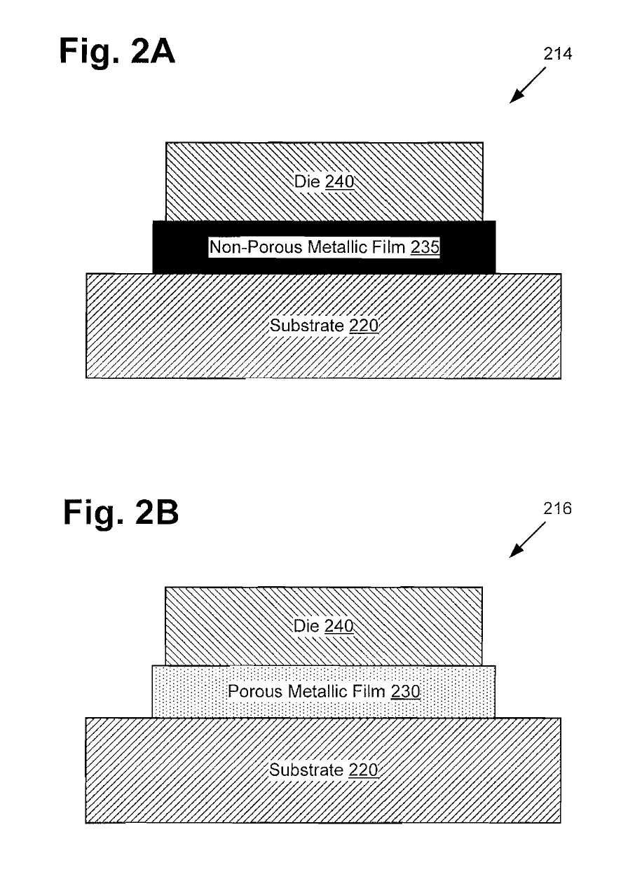

Moving to FIG. 2A, FIG. 2A illustrates a cross sectional view of a semiconductor package utilizing a non-porous metallic film as a die attach. Package 214 of FIG. 2A includes substrate 220, non-porous metallic film 235, and die 240. With respect to FIG. 2A, substrate 220 may correspond to substrate 120 from FIG. 1A, and die 240 may correspond to die 140 from FIG. 1A.

To replace lead-free solder as a die attach in a package, it has been proposed to sinter a prefabricated solid silver film directly between a silicon die and a copper substrate. Thus, substrate 220 may comprise a DBC substrate, non-porous metallic film 235 may comprise a solid silver film, and die 240 may comprise a silicon die such as a power module. As discussed above, by applying low mechanical pressure and moderate temperature, non-porous metallic film 235 may form a sintered bond between die 240 and substrate 220.

However, because non-porous metallic film 235 is solid, a high elastic modulus may be demonstrated, which may be a distinct disadvantage in situations where package 214 may be subject to temperature cycling, such as the repeated reflows required in a lead-free board level assembly, or in harsh environmental conditions such as in automotive applications. Since the coefficients of thermal expansion between die 240 and substrate 220 may differ by a large amount, for example by 15 ppm/degree C., a lower elastic modulus to relieve stress during cycling is preferable for a reliable bond.

Thus, FIG. 2B illustrates a cross sectional view of a semiconductor package utilizing a porous metallic film as a die attach, according to an embodiment of the invention. With respect to FIG. 2B, like numbered elements may correspond to similar elements from FIG. 2A. However, as shown in package 216 of FIG. 2A, a porous metallic film 230 is utilized rather than the non-porous metallic film 235 in package 214 of FIG. 2A. For example, porous metallic film 230 may comprise a porous silver film.

As a first step, porous metallic film 230 may be applied to substrate 220. In some embodiments, porous metallic film 230 may be obtained as a prefabricated film from commercial sources. For example, GE Power & Water—Water & Process Technologies Labstore offers prefabricated porous silver films intended for particle filtration applications, including films having pore sizes from 0.2 μm to 5 μm in diameter and 50 μm in thickness. In this case, porous metallic film 230 may be obtained and placed onto substrate 220.

In alternative embodiments, porous metallic film 230 may be applied to a surface such as substrate 240 by direct formation, and thus may be integrated at the wafer level or substrate level to streamline assembly and reduce costs. For example, it is known to use an electroplating process to produce a porous silver film on a surface, for example by promoting hydrogen evolution at the cathode during the electrodeposition process. In another example, it is known to spray or screen silver carbonate particles on a surface, which may include nano-sized particles, followed with a subsequent heat treatment to reduce the silver carbonate to a porous silver film. Whether prefabricated or directly formed on a surface, the thickness of porous metallic film 230 may be tightly controlled, advantageously allowing the precise fabrication of package 216 to specific tolerances.

Next, by applying low mechanical pressure, for example below 10 MPa, and moderate temperature, for example 200 to 300 degrees C., to porous metallic film 230, a solid state sintered bond may be established with die 240 and substrate 220. Accordingly, a backside of die 240 may be electrically and mechanically connected to substrate 220. Due to the porosity of porous metallic film 230, which may comprise pores from 0.2 μm to 5 μM in diameter, porous metallic film 230 may demonstrate a lower effective elastic modulus compared to non-porous metallic film 235. More specifically, the porous nature of porous metallic film 230 provides compliance for stress relief during temperature cycling, similar to the ductility of conventional high lead solder. Thus, porous metallic film 230 can form a conformal die attach between die 240 and substrate 220, creating a highly reliable sintered bond capable of withstanding significant temperature cycling. Moreover, because the total surface area of porous metallic film 230 effectively contacting die 240 and substrate 220 in FIG. 2B is less than the total surface area of non-porous metallic film 235 effectively contacting die 240 and substrate 220 in FIG. 2A, less mechanical pressure may be required to form the sintered bond in package 216 compared to package 214.

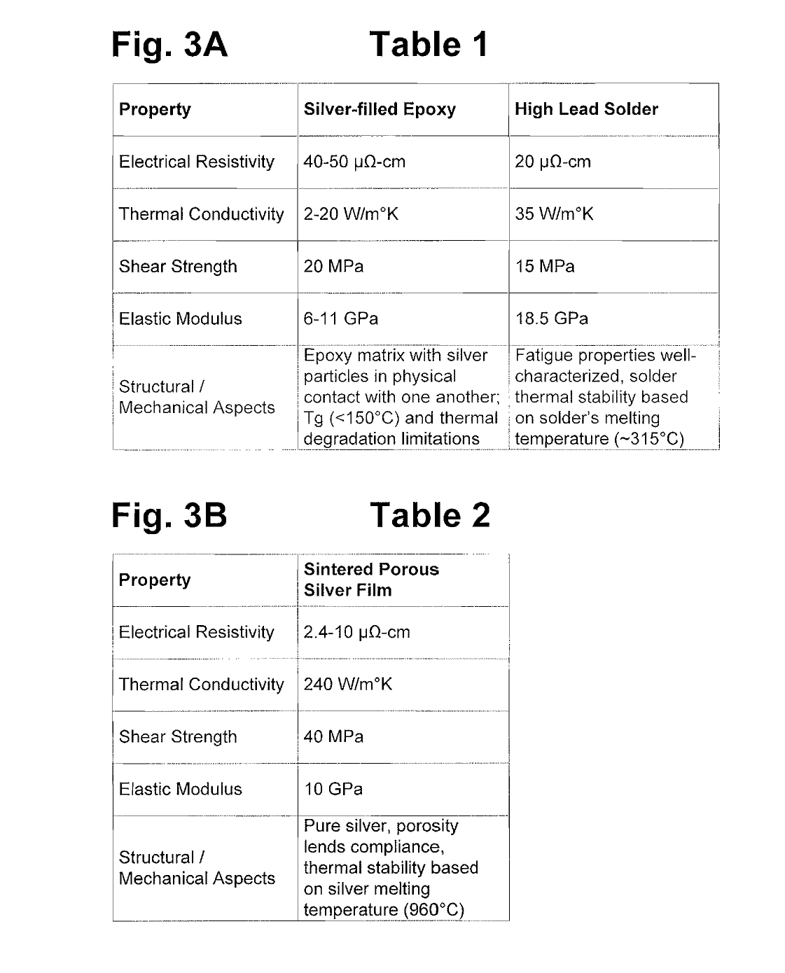

Turning to FIG. 3A, FIG. 3A illustrates a table comparing properties of conventional materials for die attach and interconnect within a package. As shown in Table 1 of FIG. 3A, conventional adhesive epoxies such as silver-filled epoxy are only suitable for low performance applications due to their high electrical resistivity (40-50 μΩ-cm) and low thermal conductivity (2-20 W/m° K). Additionally, the structural and mechanical aspects of adhesive epoxies may be insufficient to withstand repeated temperature cycling. Thus, conventional adhesive epoxies may be insufficient for power modules requiring a high performance, high reliability die attach or interconnect.

Turning to high lead solder, it is shown that electrical resistivity is decreased (20 μΩ-cm) and thermal conductivity is increased (35 W/m° K) compared to adhesive epoxy. Moreover, the properties of high lead solder are well known and the solder alloy melting temperature may be set appropriately high enough (˜315° C.) to provide sufficient thermal stability to withstand multiple reflow operations. However, as discussed above, due to the toxicity of lead, it is desirable to find a lead free alternative to high lead solder for use as a die attach and interconnect.

Accordingly, FIG. 3B illustrates a table showing properties of sintered porous metallic films for die attach and interconnect within a package, according to an embodiment of the invention. More specifically, Table 2 of FIG. 3B illustrates the properties of sintered porous silver film, as silver has material properties that are especially suitable to provide a high performance, high reliability bond. However, alternative metals or metallic compounds, for example copper, may also be considered for cost performance or other reasons.

By comparing Table 2 of FIG. 3B and Table 1 of FIG. 3A, it can be observed that sintered porous silver films can provide orders of magnitude in superior performance through low electrical resistivity (2.4-10 μΩ-cm) and high thermal conductivity (240 W/m° K). Thus, sintered porous metallic films may be especially suited for power modules and other devices requiring extremely high performance. Additionally, sintered porous metallic films also exhibit higher shear strength (40 MPa versus 20 MPa of silver filled epoxy and 15 MPa of high lead solder) and lower elastic modulus (10 GPa) than high lead solder (18.5 GPa), even attaining levels of compliance on par with adhesive epoxies (6-11 GPa). Moreover, since the thermal stability is based on the melting temperature of the film material, in this case pure silver that melts at 960 degrees C., the sintered bond is highly robust against thermal stresses. Thus, as confirmed by the properties illustrated in Table 2 of FIG. 3B, a high reliability, high performance sintered bond may be provided using prefabricated or applied porous metallic films as a die attach or interconnect, as described above.

From the above description of the invention it is manifest that various techniques can be used for implementing the concepts of the present invention without departing from its scope. Moreover, while the invention has been described with specific reference to certain embodiments, a person of ordinary skills in the art would recognize that changes can be made in form and detail without departing from the spirit and the scope of the invention. As such, the described embodiments are to be considered in all respects as illustrative and not restrictive. It should also be understood that the invention is not limited to the particular embodiments described herein, but is capable of many rearrangements, modifications, and substitutions without departing from the scope of the invention.

1. A semiconductor package comprising:
a semiconductor die situated on a substrate;
a die attach mechanically connecting a backside of said semiconductor die to said substrate, said die attach comprising a porous metallic film forming a sintered connection between said semiconductor die and substrate.

2. The semiconductor package of claim 1, wherein said die attach electrically connects said backside of said semiconductor die to said substrate.

3. The semiconductor package of claim 1, wherein said porous metallic film is a silver metallic film.

4. The semiconductor package of claim 1, wherein said porous metallic film is a copper metallic film.

5. The semiconductor package of claim 1, wherein said porous metallic film comprises pores from 0.2 μm to 5 μm in diameter.

6. The semiconductor package of claim 1, wherein said substrate is a direct bonded copper (DBC) substrate.

7. The semiconductor package of claim 1, wherein said porous metallic film is a prefabricated film.

8. A semiconductor package comprising:
a semiconductor die situated on a substrate;
at least one electrical connection between an electrode on an active surface of said semiconductor die and said substrate, said at least one electrical connection comprising a porous metallic film forming a sintered connection between said electrode and substrate.

9. The semiconductor package of claim 8, wherein said porous metallic film is a silver metallic film.

10. The semiconductor package of claim 8, wherein said porous metallic film is a copper metallic film.

11. The semiconductor package of claim 8, wherein said porous metallic film comprises pores from 0.2 μm to 5 μm in diameter.

12. The semiconductor package of claim 8, wherein said substrate is a direct bonded copper (DBC) substrate.

13. The semiconductor package of claim 8, wherein said porous metallic film is a prefabricated film.

14. A method for fabricating a semiconductor package, the method comprising:
applying a porous metallic film to a substrate;
electrically and mechanically connecting a backside of a semiconductor die to said substrate by sintering said porous metallic film and applying a first mechanical pressure to said porous metallic film, thereby forming a conformal die attach from said porous metallic film.

15. The method of claim 14 wherein said first mechanical pressure is less than a second mechanical pressure utilized for a non-porous metallic film to electrically and mechanically connect said backside of said semiconductor die to said substrate.

16. The method of claim 14, wherein said sintering is carried out using a temperature from 200 degrees C. to 300 degrees C.

17. The method of claim 14, wherein said first mechanical pressure is below 10 MPa.

18. The method of claim 14, wherein said applying is by placing a prefabricated film on said substrate.

19. The method of claim 14, wherein said applying is by electrodeposition.

20. The method of claim 14, wherein said applying is by spraying silver carbonate particles followed by a heat treatment to form said porous metallic film.
